(19) United States
(12) Patent Application Publication
(10) Pub. No.: US 2006/0125092 A1
(43) Pub. Date: Jun. 15, 2006

(54) High density integrated circuit package architecture

(76) Inventor: Paul N. Marshall, Avon, CT (US)

Correspondence Address: CANTOR COLBURN, LLP, 55 GRIFFIN ROAD SOUTH, BLOOMFIELD, CT, 06002, US

(21) Appl. No.: 11/335,112

(22) Filed: Jan. 19, 2006

Related U.S. Application Data
(63) Continuation-in-part of application No. 09/618,771, filed on Jul. 18, 2000, now Pat. No. 6,353,264.

(51) Int. Cl. H01L 23/34

(52) U.S. Cl. 257/723

(57) ABSTRACT

An integrated circuit (IC) package includes a circuitry wafer having a substrate on which is carried an optical IC configured to emit an optical signal transversely to the substrate, the substrate having an optical signal path therethrough. The first optical IC is positioned for signal communication through the signal path. Alternatively, a package includes a wafer and a cooling plate layered therewith, and the cooling plate has an optically transparent signal path therethrough and the optical IC is aligned with the signal path in the cooling plate. In yet another embodiment, an IC package includes two wafers each having a substrate on which is carried an optical IC, and a cooling plate layered between the wafers, wherein the cooling plate includes an optically transparent signal path. The optical ICs are aligned with the cooling plate signal path for optical signal communication therethrough.

### CROSS-REFERENCE TO RELATED APPLICATIONS

The present application is a continuation-in-part application of U.S. patent application Ser. No. 09/618,771 filed Jul. 18, 2000, which claims priority to Provisional U.S. Patent Application No. 60/474,005 filed May 29, 2003, both with which are each hereby incorporated by reference in their entirety.

### BACKGROUND OF THE INVENTION FIELD OF THE INVENTION

This invention relates to integrated circuitry and, in particular, to the architecture of a high density integrated circuit package.

Modern computers and other electronic devices make use of integrated circuitry, which is favored for its efficiency of manufacture, speed of operation and low power consumption. As is known in the art, these advantages increase as the density of circuit elements in the integrated circuitry grows. Conversely, these advantages can be diminished by the inadequate removal of heat produced by the operation of the integrated circuit, by the introduction of lengthy connectors between integrated circuit chips and other such factors. In designing packaging for integrated circuits, it is generally desired to pursue an architecture that enhances the advantages of the integrated circuitry.

### RELATED ART

Published United States patent application number US 2002/0053726 A1 of Mikubo et al., entitled “Semiconductor Device Attaining Both High Speed Processing And Sufficient Cooling Capacity”, filed Nov. 8, 2001, discloses a semiconductor device in which a plurality of wiring boards carry semiconductor modules (e.g., memory chips) and an integrated circuit chip (IC chip) that is connected to the wiring board. The IC chip carries a micro miniature heat sink layered with it. A plurality of the wiring boards are stacked one above the other and the circuits thereon are interconnected via socket connectors. A coolant is flowed through the heat sinks on each of the IC chips in the stack of wiring boards (see paragraph 0055 and FIGS. 5 and 6). A heat sink may be formed from two metal blocks, one of which has a series of fins that define grooves on one surface and the other of which has a mating surface for the fins. The blocks are secured together with the fins of the first block pressing against the receiving surface of the second block to form a plurality of channels between the two blocks. See paragraphs 0079 through 0086.

### SUMMARY

An integrated circuit package comprises a first circuitry wafer comprising a first substrate on which is carried a first optical IC configured to emit an optical signal transversely to the first substrate, the first substrate comprising a first optical signal path therethrough and wherein the first optical IC is positioned for signal communication through the first optical signal path.

In one embodiment, a package further comprises a second optical IC on the first substrate, the second optical IC being configured to receive optical signals emitted transversely to the first substrate, wherein the first optical IC and the second optical IC aligned with the first optical signal path for mutual optical communication therethrough.

In another embodiment, a package further comprises a second circuitry wafer comprising a second substrate on which is carried a second optical IC configured to receive optical signals emitted transversely to the second substrate and wherein the first optical IC and the second optical IC are aligned with the optical signal path for mutual optical communication therethrough. Optionally, the package includes a first cooling plate that comprises a second optical signal path therethrough, and wherein the first optical IC and the second optical IC are aligned with the first optical signal path and the second optical signal path for mutual optical communication therethrough.

In an alternative embodiment, an integrated circuit package comprises a first circuitry wafer comprising a substrate on which is carried a first optical IC; and a first cooling plate layered with the circuitry wafer, wherein the first cooling plate comprises a first optically transparent signal path and wherein the first optical IC is aligned with the first optically transparent signal path for optical signal communication therethrough.

In yet another embodiment, an integrated circuit package comprises a first circuitry wafer comprising a first substrate on which is carried a first a first optical IC; and a second circuitry wafer comprising a second substrate on which is carried a second optical IC; and a first cooling plate layered between the first and second circuitry wafers, the first cooling plate comprising a first optically transparent cooling plate signal path. The first optical IC and the second optical IC are aligned with the first optically transparent cooling plate signal path for optical signal communication therethrough.

Optionally, the first substrate comprises a first substrate optical signal path therethrough and wherein the first substrate optical signal path and the first cooling plate optical signal path are aligned with each other and the first and second optical ICs are aligned with the first substrate optical signal path and the first cooling plate optical signal path.

### BRIEF DESCRIPTION OF THE DRAWINGS

FIG. 1A is a schematic perspective view of an integrated circuit package according to one particular embodiment of the present invention;

FIG. 1B is an exploded view of the integrated circuit package of FIG. 1A;

FIG. 2 is a schematic perspective view of a circuit substrate in the integrated circuit package of FIG. 1 A, showing communication/power bus wiring and signal paths on the substrate;

FIG. 3 is a schematic perspective view of an array of integrated circuit chips mounted on the communication/power bus wiring of the substrate of FIG. 2;

FIG. 4 is a schematic exploded perspective view of a cooling plate in the integrated circuit package of FIG. 1A;

FIG. 5 is a schematic cross-sectional view of the integrated circuit package of FIG. 1A;

FIG. 6 is a schematic representation of an integrated circuit package according to this invention, showing mutually orthogonal directions of cooling, data and power through the package;

FIG. 6A is a schematic perspective view of an integrated circuit package with two cooling manifolds according to this invention;

FIG. 6B is a schematic perspective view of an IC package according to another embodiment of this invention;

FIG. 6C is a schematic perspective view of a modular connector configured to electrically engage the circuitry wafers of the package of FIG. 6B;

FIG. 6D is a schematic, exploded, perspective view of a cooling manifold for a rectangular IC package according to this invention;

FIG. 7 is a plot of surface area density for an integrated circuit package according to this invention;

FIG. 8 is a plot showing the relationship between bus capacity and surface area in an integrated circuit package according to this invention; and

FIG. 9 is a plot showing the relationship between power dissipation and surface area in an integrated circuit package according to this invention.

### DETAILED DESCRIPTION OF THE INVENTION AND PREFERRED EMBODIMENTS THEREOF

In an integrated circuit (IC) package, one or more circuitry wafers optionally are layered with one or more cooling plates. Each circuitry wafer comprises a substrate with one or more integrated circuit chips thereon. Signal communication to and from at least one IC chip on a circuitry wafer is provided through the substrate of at least one wafer or through at least one cooling plate layered with the wafer in the package. There may be IC chips mounted on both sides of a substrate, and chip-to-chip signal communication may be provided through a substrate from a chip on one surface of the substrate to a chip on the other. A cooling plate may comprise a solid, heat-sink structure or may define conduits therethrough for the flow of a heat exchange fluid. The package may optionally comprise a plurality of circuitry wafers and a plurality of cooling plates, and the cooling plates and circuitry wafers may optionally be layered alternately in the package. An integrated circuit package as described herein may have any desired geometrical shape and will optionally permit heat exchange for cooling the package and one or more of electronic power and data signal and control signal communication, to occur in three generally mutually transverse, optionally orthogonal, directions through the package. Thus, the arrangement of optional manifolds, modular connectors and other optional coupling devices that facilitate these functions from outside the package can be simpler and/or more easily designed than for prior art IC packages.

In some embodiments, an integrated circuit package comprises a plurality of circuit wafers each comprising a non-electrically conductive substrate on which is carried one or more integrated circuits with at least one wafer configured for signal communication outside the package, and a plurality of non-electrically conductive cooling plates alternately layered with the circuitry wafers, wherein the circuitry wafers and cooling plates are layered in a first direction that defines a first axis of the package, and wherein signal communication between circuitry wafers within the package occurs in a direction along the first axis, wherein the cooling plates are configured to direct heat flow in a path that is transverse to the first axis, and wherein at least one of power, data signal and control signal communication is supplied to the package from a direction that is transverse to both the first axis and the direction of heat flow.

According to one aspect, the cooling plates may define flow conduits therethrough for coolant fluid, wherein each flow conduit has two conduit ends and wherein the conduit ends are aligned at two different positions on the side of the package, and wherein the package further comprises manifolds that provide a port through which to provide coolant fluid to a plurality of flow conduits and a port to collect cooling fluid from a plurality of flow conduits, and wherein the manifolds are configured to permit access to the side of the package for providing at least one of power, data signal and control signal communication to circuitry wafers in the package.

In another embodiment, an integrated circuit package comprises a plurality of circuitry wafers each comprising a non-electrically conductive substrate on which is carried one or more integrated circuits with at least one circuitry wafer configured for signal communication outside the package, and a plurality of nonelectrically conductive cooling plates alternately layered with the circuitry wafers, and comprising circuitry wafers and cooling plates configured so that integrated circuits on at least two circuitry wafers in the package communicate with each other through an intervening cooling plate.

Optionally, an integrated circuit package as described herein comprises cooling plates that define flow conduits therethrough for coolant fluid. Each flow conduit has two conduit ends and the conduit ends may be aligned at two different sides of the package. The package may further comprise manifolds that each provide a port through which to provide coolant fluid to a plurality of flow conduits and a port to collect cooling fluid from a plurality of flow conduits. Optionally, the manifolds may be configured to permit access to the side of the package for providing power and/or control signals to circuitry wafers in the package.

Optionally, at least one cooling plate may comprise a plate signal path therethrough and a first IC on a circuitry wafer on one side of the cooling plate may be positioned for signal communication through the plate signal path. Optionally, there may be a second IC on a circuitry wafer on the other side of the cooling plate, positioned for communication with the first IC through the plate signal path. Optionally, the first IC may comprise an optical IC and the plate signal path may comprise a plate optical signal path, and the second IC may be a second optical IC.

According to another aspect, at least one circuitry wafer may comprise a substrate having a signal path therethrough and a first IC may be positioned on the substrate for signal communication therethrough. Optionally, the first IC may comprise an optical IC and the substrate signal path may be an optical signal path. Optionally, there may be a second IC on a substrate, optionally a second optical IC, positioned for signal communication with the first IC via the substrate signal path.

According to still another aspect, the circuitry wafers and cooling plates may be layered in a first direction along a first axis, and the circuitry wafers and cooling plates may be configured to permit signal communication between circuitry wafers in the first direction, the cooling plates may be configured to direct heat flow along a path that is transverse to the first axis and at least one of power, data signal and control signal communication may be supplied to the package from a direction that is transverse to both the first axis and the direction of heat flow.

In one embodiment, an integrated circuit package comprises a first circuitry wafer layered in generally parallel relation with a cooling plate, at one side of the cooling plate. The circuitry wafer comprises a substrate on which is carried a first optical IC chip configured to emit an optical signal transversely to the substrate (and transversely to the cooling plate layered parallel thereto), and the cooling plate comprises an optically transparent signal path disposed transversely therethrough to permit a transversely emitted optical signal to pass through the cooling plate. The first optical IC is aligned with the first optically transparent signal path, meaning that the signal emitted from the IC chip can pass directly from the IC chip through the cooling plate without redirection by an intervening device such as a Bragg grating. Such an embodiment may facilitate optical communication from a first optical IC chip with a device outside the package, for example, a printed circuit board on which the package is mounted, by permitting optical signal communication from a first optical IC chip to the external device via the optically transparent signal path in the cooling plate. In another embodiment, there may be a second circuitry wafer layered with the cooling plate, on the side of the cooling plate opposite from the first circuitry wafer. The second circuitry wafer has a second optical IC chip that is configured to receive and/or emit optical signals transversely to the cooling plate and that is aligned with the signal path so that is can be optically coupled (positioned for optical signal communication) with the first optical IC chip.

In another embodiment, an integrated circuit package comprises a first circuitry wafer comprising a first substrate on one surface of which is carried a first optical IC configured to emit an optical signal transversely to the first substrate. The first substrate comprises a first optical signal path therethrough and the first optical IC is positioned for optical signal communication through the first optical signal path. Optionally, there is a second optical IC chip on the substrate, on the surface opposite from the first optical IC chip. The two optical IC chips may be aligned with the optically transparent signal path so that the two chips may be optically coupled.

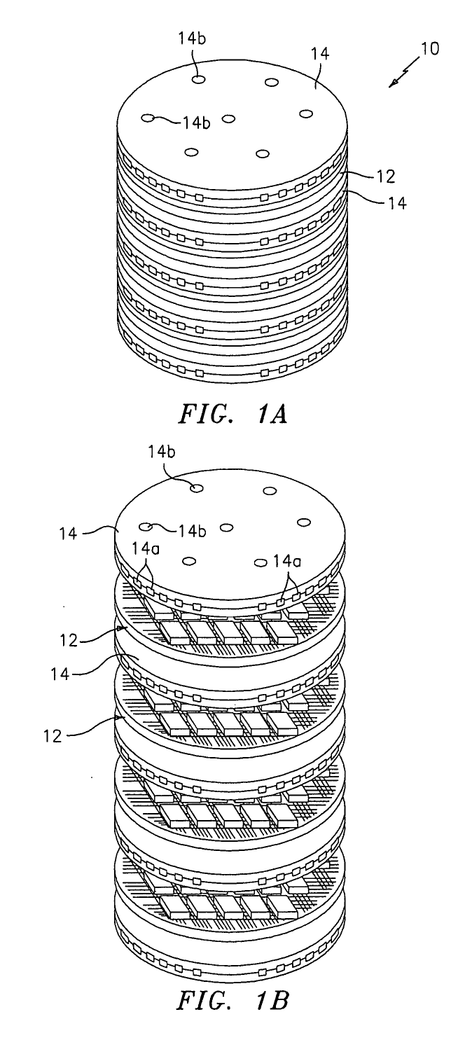

One embodiment of an IC package is shown in FIGS. 1A and 1B. IC package 10 has an optional cylindrical configuration and it comprises a plurality of circular circuitry wafers 12 arranged in substantially parallel relation to each other with a plurality of circular cooling plates 14 disposed between them to form a stack, i.e. they are layered, and preferably, the top and/or the bottom strata of the stack are cooling plates. As explained more fully below, each cooling plate optionally comprises a generally planar structure having a pair of generally planar surfaces and a plurality of channels 14a through which a cooling fluid may flow. In addition, each cooling plate 14 has one or more signal path 14b formed therein to allow electrical communication from one side of the cooling plate to the other, e.g., from a circuitry wafer immediately below the cooling plate in the stack to the circuitry layer immediately above.

The circuitry wafers and cooling plates 14 are layered in a first direction that defines a first axis of the package. Each circuitry wafer and cooling plate has a generally planar configuration, and when layered they are disposed in generally parallel relation to each other, as shown in the Figure. For purposes of discussion, a first direction (and first axis) is one transverse to the generally parallel planes of the cooling plates and circuitry wafers. Signal path 14b allow electrical signal communication, e.g., data exchange or transfer and/or the transfer of control signals, with and/or within the package in a direction generally parallel with the first axis.

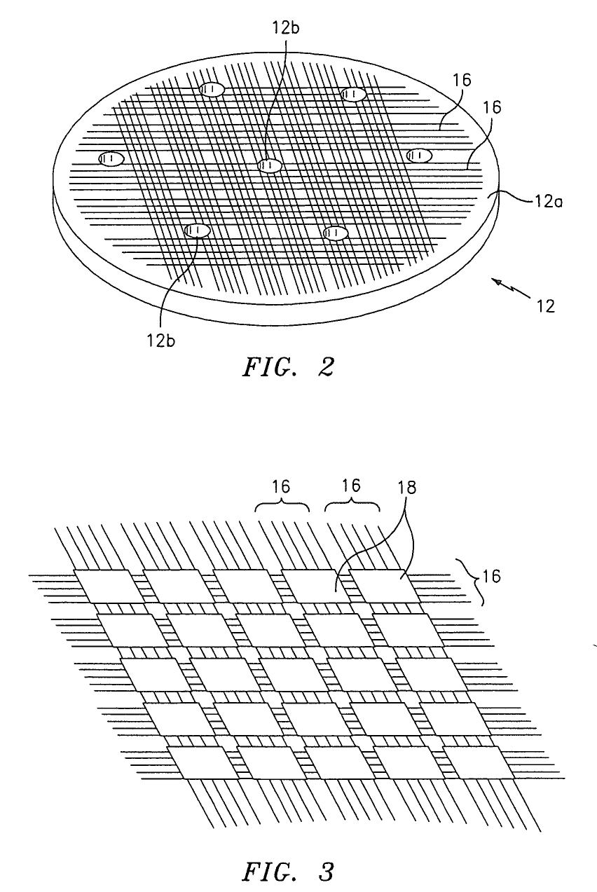

Each circuitry wafer 12 comprises a substrate 12a as shown in FIG. 2. The substrate 12a preferably comprises a layer of silicon. The substrate 12c has a generally planar configuration with two generally planar surfaces. On one surface of substrate 12a there is formed a bus channel 16, which comprises lines of electrical conductors that provide power to, and/or control and/or data signal communication with, integrated circuit chips that can be mounted on the substrate (in communication with a bus) using any suitable technology, e.g., flip chip bonding (in which an IC chip is equipped with an array of contact pads configured to coincide with matched junction points for the bus). The bus could also include control circuitry for both signal and power conditioning. Typical signal control functions provide bus contention, crossbar switches, and error correction; whereas power conditioning control functions include voltage regulation, over current protection, and error correction. By providing such circuitry in the bus channels, there will be more room for memory and processor chips to be mounted on either side of this wafer. Thus, as shown in FIG. 3, a plurality of IC chips 18, which may comprise processor chips, memory chips, or the like, can be deposited on the bus channel 16 so that the chips properly communicate with one another and can be accessed externally via outgoing and incoming bus lines on the periphery of the chip array. Optionally, a communication/power bus and array of IC chips thereon may be deposited on both sides of the substrate.

Referring again to FIG. 2, substrate 12a comprises one or more signal paths 12b, which permit signal communication through the substrate 12a. Optionally, the signal path 12b may comprise a metallic signal carrier joined to a chip or communication/power bus on opposite sides of the substrate, but preferably, signal path 12b is optically transparent (e.g., hollow or filled with a light-transmissive material such as a short length of optical fiber) so that optical signal communication can be achieved therethrough using any desired optical integrated circuit (optical IC) signaling technology, e.g., light-emitting chips such as laser chips, light-emitting diodes (LEDs), etc., and light-receiving and signaling devices such as photodiodes, phototransistors, etc.

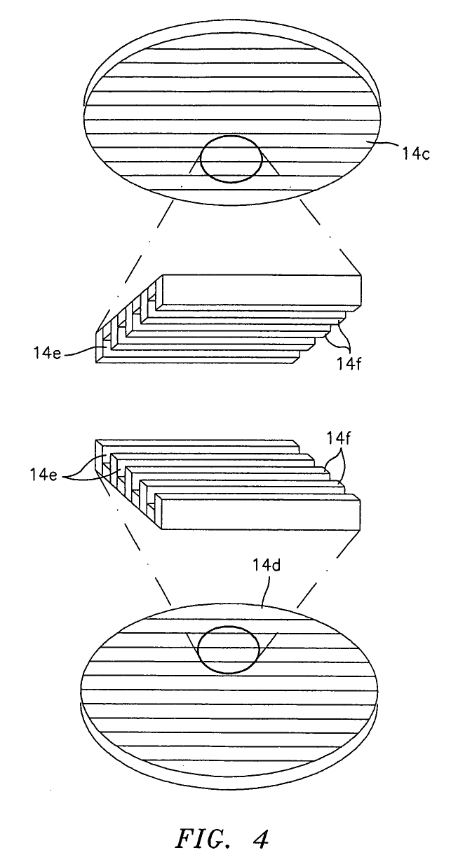

In an optional but preferred construction of the cooling plates 14 (FIGS. 1A, 1B), each cooling plate is formed from a pair of mated, plate-like cooling elements. The cooling elements are configured to have mating surfaces which, when joined together, form coolant flow channels extending through the resulting cooling plate. For example, as seen in FIG. 4, the mating surfaces of the two cooling elements 14c and 14d may have grooves 14e formed therein. The grooves are separated by ridges 14f that can be mutually aligned, so that when cooling elements 14c and 14d are secured together, they form a cooling plate 14 (FIG. 1B) having channels 14a extending therethrough. (Alternatively, the mating surface of one of the cooling elements may be flat, and the channels may be defined by ridges in the mating surface of the other cooling element.) Each channel has at least two ends so that there can be at least one inflow end through which coolant fluid can enter the cooling plate and at least one outflow end from which coolant fluid can exit the cooling plate. In the illustrated embodiment, the channels run straight through the cooling plate with their ends at opposite sides of the plate. When the cooling plates are layered in the IC package, the ends of the channels are preferably vertically aligned with each other to permit the use of inflow and outflow manifolds through which coolant fluid is easily flowed into and withdrawn from the IC package. In alternative embodiments, the channels may define serpentine or other non-linear paths through the cooling plates.

In addition to the grooves and ridges, each cooling element has optical signal paths 14b formed therein and, when the cooling elements are secured face to face to form a cooling plate 14 (FIG. 1B), optical signal paths 14b on mateing cooling elements are aligned with each other so that they can be used for signal communication from a circuitry wafer on one side of the cooling plate through to the other side of the cooling plate, e.g., to another circuitry wafer, to a communication/power bus, etc. As with the signal paths in the circuitry wafers, the cooling element signal paths may accommodate electric communication via a conductor or may be optically open (i.e., either hollow or transmissive of a light signal), for optical signal transfer therethrough.

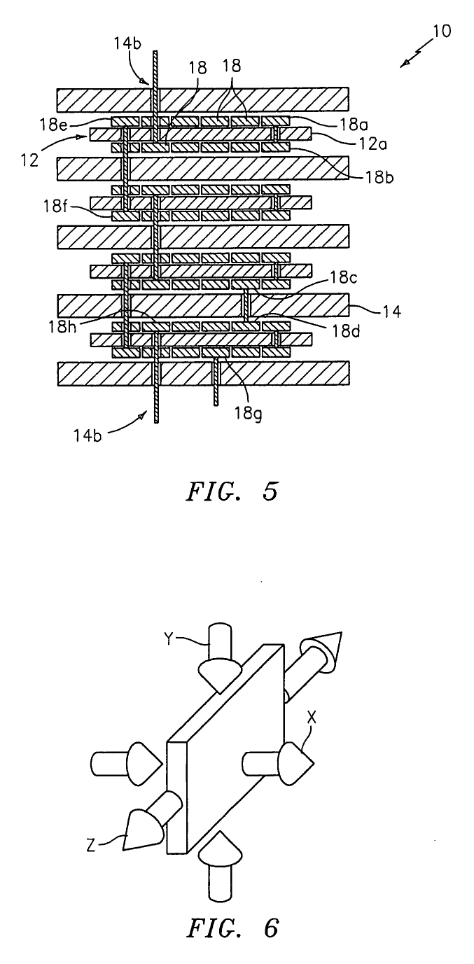

A high density IC package may be assembled by alternately layering circuitry wafers and cooling plates, as indicated in the schematic representation of FIG. 5. In the embodiment of FIG. 5, circuitry wafers 12 comprise substrates 12a that have IC chips 18 mounted on both sides of the substrates 12a. IC chips 18 include laser chips 18a-18i with associated controllers to enable laser signal communication in the circuitry within IC package 10. Laser chips 18a-18i are configured to emit and/or receive optical signals in a direction transverse to the plane of the substrate on which the chips are mounted. In other words, the IC chips are configured to emit a signal directly through the substrate without first emitting the optical signal in a direction parallel to the substrate to then be redirected transversely by means of Bragg grating or the like. For example, laser chips 18a and 18b are mutually aligned with an optical signal path in substrate 12a so that the optical circuitry on one side of substrate 12a can communicate optically with optical circuitry on the other side of substrate 12a (i.e., the two laser chips are optically coupled with each other). Similarly, laser chips 18c and 18d are mutually aligned with a signal path in a cooling plate so that chips 18c and 18d can communicate with each other optically, thus enabling the circuitry on a circuitry wafer on one side of a cooling plate to communicate through the cooling plate with circuitry on another circuitry wafer on the other side of the cooling plate. Laser chips 18e and 18f can communicate optically because they are aligned with communication apertures on their respective substrates 12a which are both aligned with a communication apertures in the intervening cooling plate 14. Thus, it is possible to align communication apertures in both circuitry wafer substrates and cooling plates to permit optical communication through both a substrate 12 and a cooling plate 14.

Laser chips 18g, 18h and 18i are aligned with optical signal paths in the outer (i.e., top and bottom) cooling plates so that they can send and receive optical signals with devices that are external to, and vertically aligned with, the IC package. (As used in this description and in the claims, the vertical direction relative to an IC package is the direction that is transverse, optionally orthogonal, to the planes in which layered circuitry wafers and cooling plates are disposed. Optionally, the vertical direction is the direction in which the circuitry wafers and cooling plates are layered.) In one embodiment, vertical communication may be used primarily or exclusively for data flow. The external device may comprise a modular optical connector, e.g., an array of optical fiber ends or of solid-state optical logic devices, configured to exchange optical signals with optical ICs in the package. Accordingly, the positioning of optical ICs 18g, 18h, etc., for vertical external communication and the pattern of corresponding communication signal paths in the outer cooling plates are matched to the external device.

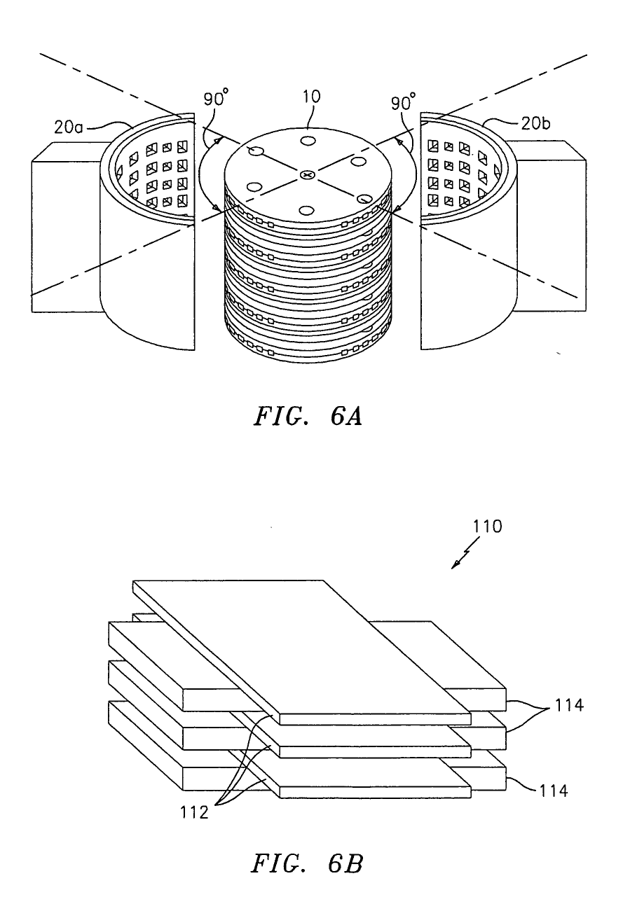

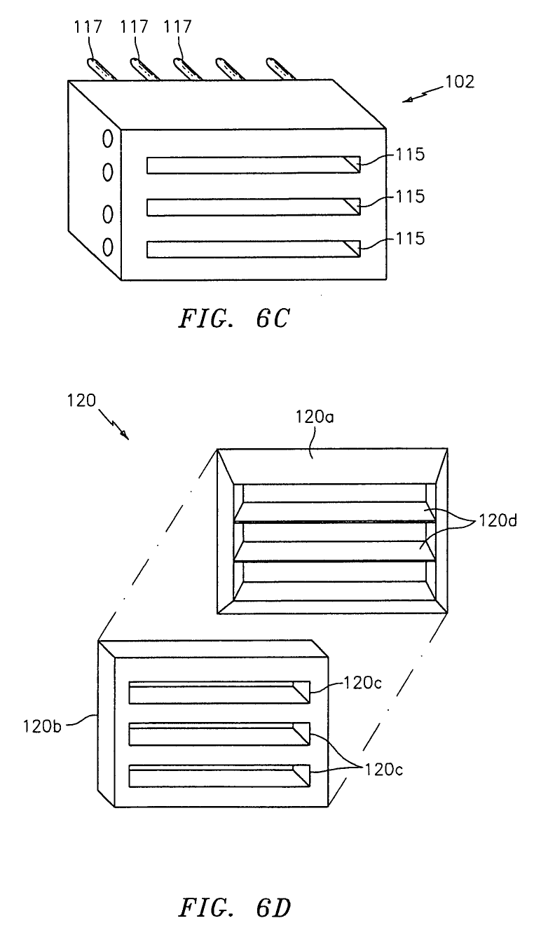

The channels flowing through the cooling plates of FIG. 5 may extend from left to right as sensed in the Figure, a direction that runs parallel to the substrates 12a. The cooling fluid may be supplied to, and collected from, the channels by manifolds which will typically be situated at opposing sides of the package to accommodate a straight fluid flow path through the package. It will therefore be appreciated that the various signal paths in the substrates 12a and cooling plates 14 permit signal communication between circuitry wafers in a vertical direction, transversely through the cooling plates and or substrates in the package. Optionally, data input and output can be directed vertically through the package 10 (as sensed in FIG. 5), whereas electrical power and (optionally) control functions can be provided in a horizontal direction (as sensed in FIG. 5) that is orthogonal to both the direction of coolant flow and the vertical flow of data signal communication, i.e., in a direction perpendicular to the plane of the paper in which FIG. 5 is depicted. Representing the IC package 10 schematically as a rectangular solid in FIG. 6, the architecture of an IC package in accordance with this invention permits coolant to flow through the package 10 in a direction along a “Z” axis. Power, data and/or control signal communication can be accommodated vertically (through the top and/or bottom surfaces and/or vertically within the package) along a vertical or otherwise upward-directed “Y” axis perpendicular to the Z axis, and/or horizontally along an “X” axis that is perpendicular or otherwise transverse to both the Y and Z axes. Power, data and control signals can be allocated to the X and/or Y axes in any desired manner and combination.

It will be understood that IC packages described herein need not be limited to rectangular configurations, although a rectangular configuration may allow for convenient connection of the package with other components in the cooling system, power supplies an other electronic components. For a cylindrical package as shown in FIG. 1A, inflow and outflow manifolds (such as manifolds 20a, 20b, FIG. 6A) can be configured to occupy only a portion of the periphery of the package, leaving the remainder of the periphery accessible for the lateral connection of a lateral bus that may optionally primarily provide power and control signals to one or more circuitry wafers.

Such inflow and outflow manifolds facilitate the flow of coolant through the package in a plurality of parallel planes that are disposed in perpendicular relation to the direction in which circuitry wafers and cooling plates are layered in the package. Thus, thermal flow through the package is achieved in a horizontal direction orthogonal to the vertical direction in which circuitry wafers and cooling plates are layered. Power and signal communication with the package may be provided in the vertical direction and/or in a direction orthogonal to the vertical direction. By positioning an electrical connector between two coolant manifolds, signal communication may also be orthogonal to the vertical direction and to the direction of heat flow through the package. As shown, inflow coolant manifold 20a occupies only a 90-degree sector of the periphery of the C package indicated by its circular footprint at 10, and outflow coolant manifold 20b occupies a diametrically opposite 90-degree sector leaving two lateral 90-degree sectors available for lateral connection to a bus for electrical signaling (e.g., for control and/or power and/or data transfer) in a direction orthogonal to the direction of flow of coolant from one manifold to the other, at the regions indicated by arrows 22. Each of manifolds 20a and 20b has a concave face for mating with the stack. Each manifold face carries a deformable gasket material for contact with the stack. The gasket material is perforated in a manner calculated to allow coolant to flow therethrough into or out from the cooling plates and to establish a seal around each of the flow channels. As shown, the gasket material on manifolds 20a and 20b have perforations to match the openings of each flow channel in the cooling layers in package 10, but, in alternative embodiments, the gasket may be configured to form a seal around a plurality of such openings in a cooling layer. Accordingly, the circuitry wafers may be configured to include edges with I/O contact pads that protrude from opposite sides of the stack, to facilitate the use of a suitably configured modular electrical connector to that package. Likewise, in an alternative to what is shown in FIG. 6A, the cooling plates may optionally be configured to protrude from the stack, to facilitate the connection of manifolds thereto. Such a connector and manifold are shown in FIGS. 6C and 6D, respectively.

In a generally rectangular embodiment, a package 110 (FIG. 6B) comprises a plurality of circuitry wafers 112 arranged in substantially parallel relation to each other with a plurality of rectangular cooling plates 114 disposed between them to form a stack. The circuitry wafers 112 and cooling plates 114 are rectangular in configuration and are disposed crosswise so that their ends protrude from the stack in mutually orthogonal (i.e., transverse) directions. The protruding ends of circuitry wafers 112 will facilitate the use of a modular electrical bus connector such as connector 102 (FIG. 6C) to facilitate the connection of package 110 to a source of power and, optionally, control signals and/or data signals for circuitry wafers 112. Connector 102 comprises a series of slots 115 that are configured to receive the ends of circuitry wafers 112 and to establish electrical connections between access pins 117 and corresponding contacts on the respective circuitry wafers 112. Connector 102 and circuitry wafers 112 can be configured in a generally conventional manner, e.g., to provide for a zero insertion force connection.

The protrusion of the ends of the cooling plates 114 in package 110 permits the use of cooling fluid manifolds that are slotted to receive the ends of the cooling plates in a manner similar to the way connector 102 receives the ends of the circuitry wafers. A suitable manifold 120, as represented schematically in FIG. 6D (in which the package 10 is shown without circuitry wafers, to simplify the drawing), may comprise a manifold frame 120a and a gasket 120b. Gasket 120b has slots 120c configured to receive the edges of the cooling plates that protrude from the stack, thus forming a seal around the plurality of flow channels in each cooling plate. The gasket 120b is disposed between the manifold frame 120a and the cooling plates, and provides a seal around the cooling plates and between the plates and the frame. Frame 120a includes wedges 120d which are configured to bear against gasket 120b between slots 120c to facilitate the formation of the seal.

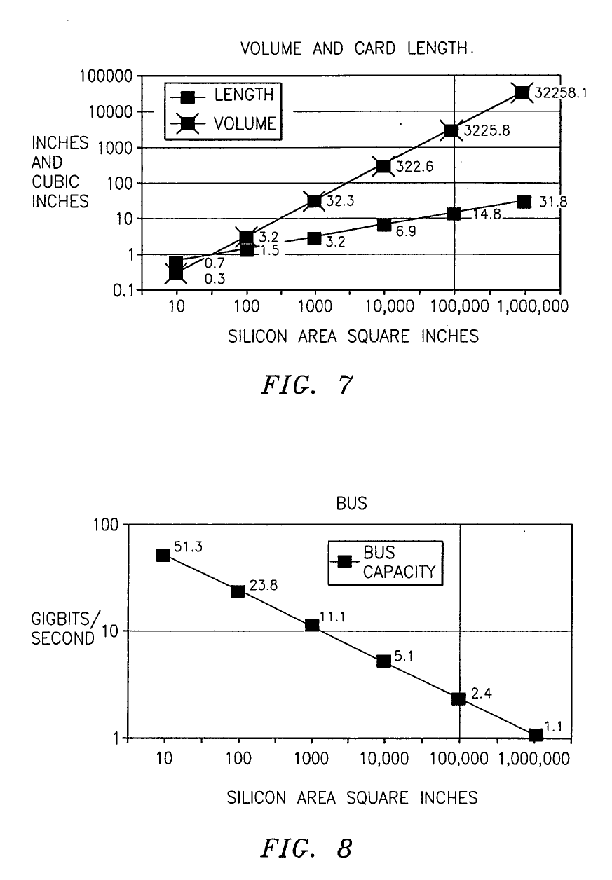

One measure of expected performance for an IC package is the amount of surface area that can be dedicated to circuitry within a given volume. The relationship of substrate surface area to volume for an IC package according to this invention is illustrated in FIG. 7. An integrated circuit package having the architecture described herein can provide thirty-two square inches of surface area for interconnected IC chips per cubic inch of volume, i.e., a surface area density D of 32 square inches per cubic inch. In a representative embodiment, D=0.8/w and w=0.025 inch, where w is the thickness of a circuitry wafer substrate and of the IC chips mounted on both sides of the substrate in the IC package, and where the thickness of the cooling plates is 2 w. The formula includes the surface areas of both sides of the surfaces of the IC chips on the substrate and both surfaces of the substrate, so that the total thickness of a circuitry layer (a substrate with chips on both sides) and an associated cooling plate is 5 w.

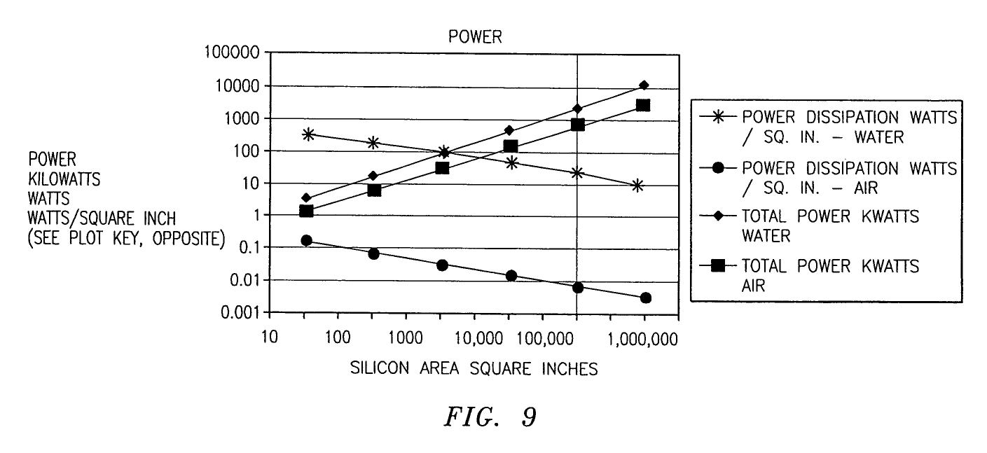

Another measure of performance is the bus capacity exhibited by the IC package. As illustrated in FIG. 8, the capacity, in gigabits per second, increases as the surface area over which a circuit is deposited decreases, because with decreased surface area there are shorter communication leads, so signals take less time to travel from one transistor (or other circuit element) to the next, making the communication line available more quickly for other signals. An integrated circuit package providing thirty-two square inches of surface area for interconnected IC chips per cubic inch of volume in accordance with this invention will accommodate data transfer at about one gigabit per second per channel. With increased bus capacity, however, there is in-creased generation of heat. The chart of FIG. 9 illustrates that in an IC package according to this invention, the amount of power consumed by the package increases as the surface area increases, but that power dissipation diminishes with increasing surface area. The power dissipation in an integrated circuit package according to this invention varies according to the type and velocity of coolant flowing through the cooling plates. The expected power dissipation (PD) at a maximum junction temperature of 70° C., using water cooling at a velocity of 8.8 feet per second is PD=339/(L+0.3) watts per square inch of silicon area, and where L is the card length in inches and, using air cooling at a velocity of 88 feet per second, the power dissipation is expected to be PD=0.0975/(L+8.65×10⁻⁵) watts per square inch.

The terms “first,” “second,” and the like, “primary,” “secondary,” and the like, as used herein do not denote any order, quantity, or importance, but rather are used to distinguish one element from another. The terms “a” and “an” do not denote a limitation of quantity, but rather denote the presence of at least one of the referenced item. The terms “front”, “back”, “bottom”, and/or “top” are used herein, unless otherwise noted, merely for convenience of description, and are not limited to any one position or spatial orientation.

While the invention has been described in connection with particular embodiments thereof, it will be understood by one of ordinary skill in the art, upon a reading and understanding of the foregoing description, that numerous alterations and variations may be made within the scope of the invention described herein.

What is claimed is:

1. An integrated circuit package comprising:
a first circuitry wafer comprising a first substrate on which is carried a first optical IC configured to emit an optical signal transversely to the first substrate, the first substrate comprising a first optical signal path therethrough and wherein the first optical IC is positioned for signal communication through the first optical signal path.

2. The package of claim 1, further comprising a second optical IC on the first substrate, the second optical IC being configured to receive optical signals emitted transversely to the first substrate, wherein the first optical IC and the second optical IC aligned with the first optical signal path for mutual optical communication therethrough.

3. The package of claim 1, further comprising a second circuitry wafer comprising a second substrate on which is carried a second optical IC configured to receive optical signals emitted transversely to the second substrate and wherein the first optical IC and the second optical IC are aligned with the optical signal path for mutual optical communication therethrough.

4. The package of claim 3, further comprising a first cooling plate that comprises a second optical signal path therethrough, and wherein the first optical IC and the second optical IC are aligned with the first optical signal path and the second optical signal path for mutual optical communication therethrough.

5. An integrated circuit package comprising:
a first circuitry wafer comprising a substrate on which is carried a first optical IC; and
a first cooling plate layered with the circuitry wafer;
wherein the first cooling plate comprises a first optically transparent signal path; and
wherein the first optical IC is aligned with the first optically transparent signal path for optical signal communication therethrough.

6. An integrated circuit package comprising:
a first circuitry wafer comprising a first substrate on which is carried a first a first optical IC; and
a second circuitry wafer comprising a second substrate on which is carried a second optical IC; and
a first cooling plate layered between the first and second circuitry wafers, the first cooling plate comprising a first optically transparent cooling plate signal path;
wherein the first optical IC and the second optical IC are aligned with the first optically transparent cooling plate signal path for optical signal communication therethrough.

7. The package of claim 6, wherein the first substrate comprises a first substrate optical signal path therethrough and wherein the first substrate optical signal path and the first cooling plate optical signal path are aligned with each other and the first and second optical ICs are aligned with the first substrate optical signal path and the first cooling plate optical signal path.
